(19) United States
(12) Patent Application Publication
(10) Pub. No.: US 2017/0113359 A1
(43) Pub. Date: Apr. 27, 2017

(54) COATED SHAVING FOIL

(71) Applicant: VECO B.V., Eerbeek (NL)

(72) Inventors: Harm Gerrit Knol, Geesteren (NL); Ahmad Dawud Ahmad Harbiye, Hilversum (NL)

(21) Appl. No.: 15/318,716

(22) PCT Filed: Jun. 17, 2015
(86) PCT No.: PCT/NL2015/050444

§ 371 Date: Dec. 14, 2016

(30) Foreign Application Priority Data
Jun. 19, 2014 (NL) 2013035

(51) Int. Cl. B26B 19/38; C23C 16/02

(52) U.S. Cl. CPC B26B 19/384; C23C 16/02

(57) ABSTRACT

A two-sided metal foil for use in an electrical shaver, which has a hair-receiving side and an opposite blade side, includes sheet of metal with a plurality of apertures through the sheet, in which at least the hair-receiving side of the foil is provided with a coating of poly(p-xylylene) and/or its derivatives.

### CROSS-REFERENCE TO RELATED APPLICATIONS

This application is the National Stage of International Application No. PCT/NL2015/050444 filed Jun. 17, 2015, which claims the benefit of Netherlands Application No. NL 2013035, filed Jun. 19, 2014, the contents of which is incorporated by reference herein.

### FIELD OF THE INVENTION

The present invention relates to coated metal foils for shaving systems, to the production of such foils, and to a shaving system comprising such foils.

The invention relates to a two-sided metal foil for use in an electrical shaver, which has a hair-receiving side and an opposite blade side, comprising a sheet of metal with a plurality of apertures through the sheet, which metal sheet is provided with a coating.

### BACKGROUND OF THE INVENTION

Such metal foils are commonly found in electrical shavers. One type of electrical shaver consists of a shear foil and an inner, moveable cutter. The foil is usually made out of metal, and has a plurality of apertures separated by metal, through which apertures hairs or stubble to be shaved can be received. The cutter is placed in close contact with the rear side (also called blade side) of the foil and typically comprises a plurality of separate blades, but may also be a cutting foil or other cutting element. Regardless of the used configuration, the cutter is moved back and forth over the apertures in the foil, which results in a shaving action when the foil is placed in close contact with the skin and the hairs or stubble enter the apertures.

During shaving, the foil not only is in close contact with the skin, but is also moved across the skin multiple times. Hence, the surface topography of the foil at the skin side is an important aspect in determining the comfort and quality of the shaving effect. Sharp edges at the skin side will deteriorate the shaving comfort, whereas rounded edges and a surface with a low friction coefficient will result in a smooth sensation on the skin. A small contact area between the cutter and the backside of the foil will reduce friction between the foil and the cutter, thereby reducing wear and heating of the instrument, which improves its lifetime. On the other hand, sharp edges between the backside of the foil and the cutter are advantageous for a good cutting action. U.S. Pat. No. 4,184,250 describes a cutter foil which answers most of these demands.

The shape of the apertures can also be an important parameter. As hairs tend to grow in distinctly different directions and also tend to exhibit differences in size, it may be favourable to have a shaving foil with apertures of different shapes and sizes. U.S.-B2-7845079 describes a shaving foil with a plurality of hair-entrance apertures wherein each aperture has a different shape, and the apertures are arranged in an amorphous fashion.

Furthermore, the material from which the foil is made is an important aspect. Some materials will result in better skin sensation than others. If the foil is produced from a skin sensitizing material, allergic skin reactions, such as redness, itching, and swelling may result. These symptoms may range from mild to severe. Although many metals can cause such symptoms, nickel, cobalt, and chromium are the metals which are most likely to induce an allergic reaction. It is estimated that about 17% of women and 3% of men are allergic to nickel and about 1-3% of the population is allergic to chromium and cobalt. Nickel however is a popular manufacturing material for shaving foils.

When a shaving foil is to be made from a skin sensitizing metal such as nickel, the application of a coating which prevents direct contact between the skin and the shaving foil will be highly advantageous. For example, a mineral coating could be utilized for such a purpose. JPH0347293 utilizes hydroxyapatite to form a coating film on the surface of a shaving blade body, which results in a sharp blade without the risk of a skin allergy and/or rough skin after shaving. Such hydroxyapatite mineral coatings however have poor mechanical properties, such as brittleness, low tensile strength and fracture toughness, resulting in a decreased lifetime of such coatings.

GB 2108154 A has disclosed a filter made from a perforated metal foil that is coated with a thin layer of an intermetallic compound of tin and nickel, in order to reduce the potential health hazard related to heavy metals like nickel in contact with ordinary and luxury foods, beverages or the like, body fluids or the skin, and to avoid the use of a protective coating of a precious metal like platinum. A preferred embodiment is a nickel coffee filter, wherein the intermetallic layer of tin and nickel has a thickness in the range of 1-3 micrometres and a very thin gold coating of 0.05-0.5 micrometres.

If a coating is applied to a metal body of a shaving foil, the coating has to be thin, e.g. 1-2 micrometres in view of the cutting action. In particular, the sharp edges of the apertures in the metal body need to be retained. If a thicker metallic coating would be applied, the edges would become rounded thereby affecting the cutting action. However, such thin coatings of a metal or metal alloy on a metal body have so called pinholes (very small openings or cracks through the coating extending from the top side to the bottom side thereof). In contact with body fluids, like sweat, a galvanic cell comprising the metallic coating and metal body is established, with the result that in view of potentials of the metal body and metallic coating respectively, either the body or the coating is subjected to corrosion. Holes of 10 micrometres and more in the metal body under a pinhole or crack in a coating of a more noble metal have been observed.

### SUMMARY OF THE INVENTION

It is an objective of the current invention to provide a metal foil for use in an electrical shaver that is coated with a coating with favourable mechanical properties, such that no allergic reactions will take place upon repeated use of an electrical shaver comprising such a foil.

Another objective of the invention is to increase the lifetime of both the foil and the cutter.

Yet another objective of the invention is to provide a coated shaving foil, which is not subject to corrosion either of the body or of the coating itself.

According to the invention, in the two-sided metal foil for use in an electrical shaver, which has a hair-receiving side and an opposite blade side, comprising a sheet of metal with a plurality of apertures through the sheet, therefore at least the hair receiving side of the foil is provided with a coating of poly(p-xylylene) and/or its derivatives.

In the invention, poly(p-xylylene)s, also known by their trade name parylene, are used as coating materials because of several reasons. Firstly, parylene has favourable mechanical properties and resists the effects of organic solvents, acids, and inorganic reagents.

Secondly, it is biocompatible, non-allergic, bio-stable, lubricious, moisture resistant and can be sterilized. Also, the production of parylene utilizes so-called “green polymer chemistry” as the polymerization from the commonly used precursor [2.2]paracyclophane and its derivatives is self-initiated and un-terminated, with no solvent or catalyst required. In case of the poly(p-xylylene coating according to the invention no galvanic cell can be formed, even if the coating shows pinholes or small cracks. As a result corrosion—although it occurs to some extent—is much slower (about 200-500 times) than in case a galvanic cell is established.

A least the hair-receiving side of the metal foil is coated, as this is the side that contacts the skin. A coating on this side will prevent an allergic reaction due to nickel touching the skin.

Preferably the coating of poly(p-xylylene) and/or its derivatives is a conformal coating. Conformal means that the coating has almost the exact same thickness everywhere. Polymer coatings can have a wide range of mechanical and other properties depending on the specific type of polymer. These materials are also known for their cost-effectiveness, but generally have the problem that they have to be applied from a melt or solution, and as such exhibit liquid properties such as surface tension and meniscus. As a result of this, not all features of a material such as sharp edges, slots and crevices may be coated with an equally thick layer of polymer. This may result in a decreased effectiveness of the coated part or material, and also some parts of the coating may wear off quicker than other parts, reducing the overall effectiveness of the coating as well. A parylene film can be formed on surfaces from a high purity precursor powder with no liquid stage. As a consequence, the resulting film can be very thin, is conformal, meaning that the film has almost the exact same thickness everywhere, and has no pinholes or other irregularities. Thus, when a metal shaving foil is coated with parylene, all features of the foil are coated with an equally thick layer of the coating. Because of this the favourable shaving properties of the foil are retained.

In a typical coating process, the dimer [2.2]paracyclophane and/or its derivatives are vaporized at a temperature above room temperature to form dimeric gas molecules. The gas molecules are subsequently cleaved to the monomer form in a second stage by heating to a higher temperature than the vaporization temperature. The active monomer gas is then introduced to an evacuated coating chamber. The object to be coated is exposed to the monomer gas in this coating chamber under reduced pressure, preferably at room temperature. It goes without saying that when the object is exposed to a mixture of different [2.2]paracyclophane species, a copolymer will result. In the process, all faces of the object are uniformly impinged by the gaseous dimer, which converts to the gaseous monomer. This results in the deposition of a conformal polymer layer when the monomer contacts the object to be coated. After the process, the coating chamber is depleted of any monomer and dimer gas, and the coated object can be removed.

The general chemical formula for poly(p-xylylene), its derivatives and the dimer is presented below.

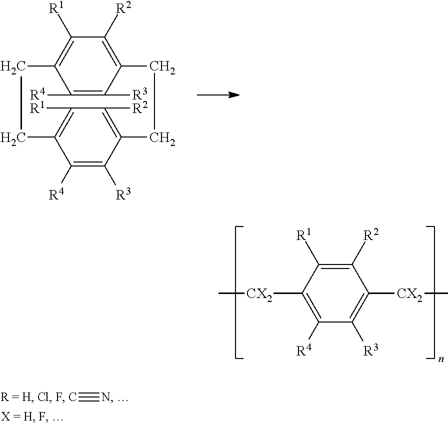

When R¹⁻⁴=H and X=H, the polymer coating is poly(p-xylylene), also known as parylene N. Substituting one or more of the R and/or X groups will result in a poly(p-xylylene) derivative. For example, for R¹=Cl, R²⁻⁴=H and X=H, the polymer coating is poly(chloro-p-xylylene), also known as parylene C. Other possibilities are poly(α,α,α′,α′-tetrafluoro-p-xylylene), also known as parylene HT (R¹⁻⁴=H, X=F), and poly(dichloro-p-xylylene), also known as parylene D (R^{1,3}=Cl, R^{2,4}=H, X=H), amongst many others.

Preferably the coating is a halogen containing poly(p-xylylene). Because of their higher density, halogen containing derivatives of poly(p-xylylene) have better barrier properties than unsubstituted poly(p-xylylene).

More preferably the coating is poly(chloro-p-xylylene). Its density is lower than that of many other halogen containing poly(p-xylylene) derivatives, allowing an easy synthesis of the coating material.

Preferably, all faces of the metal sheet including the walls that extend from the hair receiving side to the blade side and which walls delimit the apertures, are provided with a coating of poly(p-xylylene) and/or its derivatives, as this simplifies the coating process. If the metal sheet is to be coated only on the hair-receiving side, the metal sheet should be placed onto a fixture at the blade side, or the blade side should otherwise be covered during deposition. In the simplest process however, wherein all faces of the sheet can be coated, the metal sheet or even multiple sheets to be coated are simply put into a rotating cylinder within the coating chamber, and kept in motion throughout the deposition process. This results in an even coating on all faces of the sheet or sheets.

Preferably the thickness of the coating of poly(p-xylylene) and/or its derivatives is in the range of 1-10 micrometres. In a coating having this thickness, nickel migration is at an acceptable level according to NEN-EN 12472, preventing an allergic skin reaction. Too low thickness values result in nickel migration limits that might cause an allergic skin reaction, whereas thickness values higher than 10 micrometres do not further reduce the nickel migration compared to the nickel migration at a thickness of 10 micrometres. The thickness of the coating can be suitably controlled by adjusting vapour pressure, coating time, and temperature.

More preferably the thickness of the coating of poly(p-xylylene) and/or its derivatives is in the range of 3-5 micrometres, as this thickness provides the optimum balance between the limiting effect on nickel migration and the amount of material that is needed and thus material costs.

A variety of metals or alloys can be used for the manufacture of a shaving foil. Examples of metals are chromium, copper, titanium, aluminium, etc. Alloys can include steel, brass, and other alloys. Preferably, the metal of the metal sheet is nickel. Nickel objects can especially be easily formed by electroforming.

A foil may comprise different kinds of apertures: functional and cosmetic apertures. Functional apertures aid in providing the shaving action, whereas cosmetic apertures primarily have cosmetic goal, and do not necessarily aid in the shaving action. Preferably the functional apertures in the metal foil are in the range of 200-600 micrometres in diameter. This provides the optimum balance between a size big enough for stubble to easily enter the apertures, yet small enough to provide an effective shaving treatment. If the apertures are too small, hair cannot easily enter the apertures. If the apertures are too big, then the blade will not be able to cut off all the hairs entering the apertures at the skin base, resulting in a reduced shaving effectiveness, as short stubble can remain on the skin. It will also result in faster wear of the blade.

Preferably the foil has a thickness in the range of 30-60 micrometres. This provides the optimum balance between structural integrity of the foil and ease of manufacturing: Thinner foils can deform too easily, resulting in a reduced shaving efficiency, whereas thicker foils have a negative impact on the shaving result. Because of the thickness of the foil, the shaver is placed farther from the skin, which results in a reduced shaving efficiency. Also more materials is needed to produce thicker foils, which is more costly.

Preferably, at the blade side the plate partition (that is to say the metal material of the metal sheet separating the apertures) comprises cut-aways, and surrounding these cut-aways the plate partition comprises a flat surface parallel to the foil plane. Because the blade or blades are in close contact with the flat surface parallel to the foil plane, and the preferably sharp transition between the hair-receiving side and the wall, an efficient shaving action is possible. Because of the cut-aways, the flat surface surrounding the cut-aways, which also is the contact area of the foil with the cutter, is minimized, such that friction between the foil and the cutter is reduced, thereby also reducing wear and heating of the instrument. This increases the lifetime of both the foil and the cutter.

The current invention also provides for a method of manufacturing a metal foil for use in an electrical shaver, comprising: exposing a two-sided metal foil, which has a hair-receiving side and an opposite blade side, comprising a sheet of metal with a plurality of apertures through the sheet, to a gas of [2.2]paracyclophane and/or one or more of its derivatives, thereby depositing a coating of poly(p-xylylene) and/or its derivatives onto the metal sheet.

Finally, the current invention also provides for a shaving apparatus comprising a two-sided metal foil for use in an electrical shaver as previously described.

The examples, advantageous and preferred embodiments presented above regarding the shaving foil according to the invention are equally applicable to these further aspects of the invention.

In a preferred embodiment the sheet of metal having a plurality of apertures is prepared by electroforming.

### BRIEF DESCRIPTION OF THE DRAWINGS

The invention is further illustrated by means of the attached drawings, wherein:

FIG. 1 is a schematic top view of an embodiment of a foil for use in an electrical shaver.

FIG. 2 is a schematic cross-sectional view of an embodiment of a foil for use in an electrical shaver illustrating several steps in the manufacturing process.

FIG. 3 is a schematic cross-sectional view of an embodiment of a foil according to the invention for use in an electrical shaver.

### DETAILED DESCRIPTION OF THE INVENTION

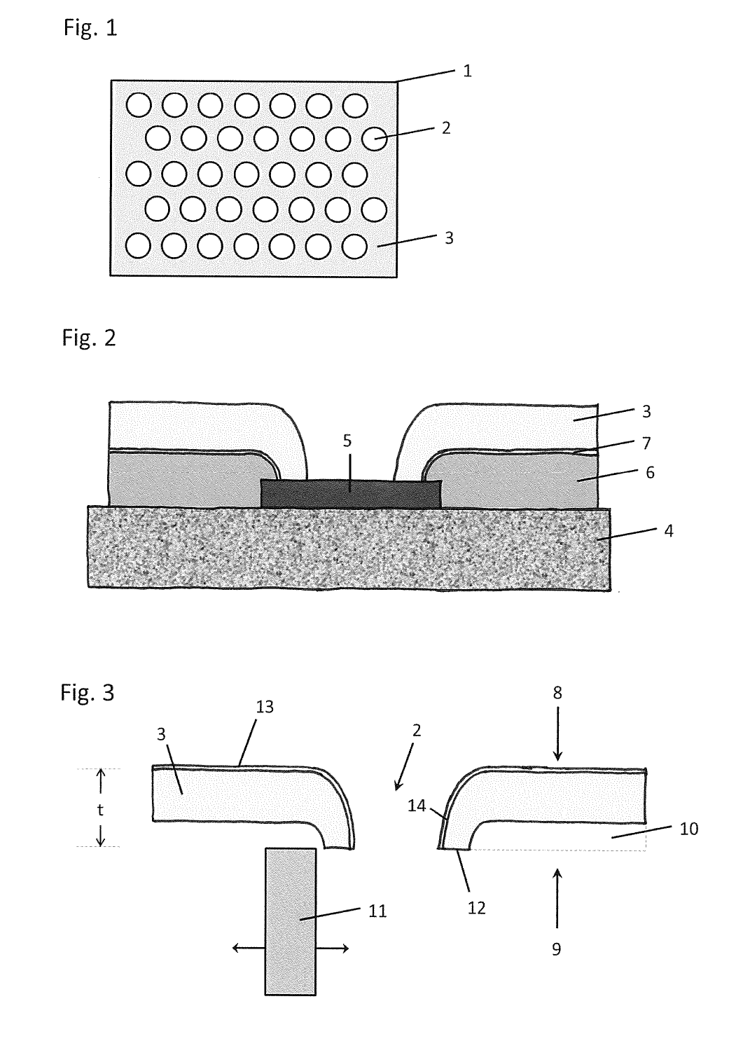

FIG. 1 provides a schematic top view of a foil 1 for use in an electrical shaver exposing the hair receiving side. The foil comprises a sheet of metal 3, in which a plurality of apertures 2 through the sheet 3 are provided. The apertures are drawn as circular, but may have other shapes, such as circles, ovals, triangles, squares, rectangles, pentagons, hexagons, heptagons, octagons, diamonds, amorphous shapes, or any other possible shape as well as combinations of these. The density of apertures is arbitrary as well. More apertures, i.e. a higher density, lead to more hairs or stubble entering the apertures, decreasing the amount of necessary movement of the foil across the skin in order to capture all the hair or stubble. Too many apertures however will lead to a weakening of the plate partition 3, as in such a case there is not enough metal to support the structure.

FIG. 2 provides a schematic cross-sectional view illustrating a manufacturing process of a foil for use in an electrical shaver according to the current invention. On an electrically conductive substrate 4 a pattern of a photo-resist 5 is applied. This combination of conductive and non-conductive surfaces is called the mould or die. Subsequently, the mould is placed in a galvanic bath, and on the conductive sections of this mould a first nickel layer 6 is deposited galvanically. The mould with the deposited metal layer is then taken out of the bath and passivated by applying a passivating layer 7. This passivating layer can consist of e.g. a metal oxide, an organic compound, or sulphite. The entire mould is then placed back in a galvanic bath and a second layer of metal 3 is deposited. Because of the passivating layer in between both metal layers, both layers can be separated from each other. The second layer will be the sheet of metal 3 in the final foil for use in an electrical shaver.

FIG. 3 provides a schematic cross-sectional view of a foil 1 for use in an electrical shaver according to the current invention. The top side is the hair-receiving or skin side 8. The top side and upstanding walls 14 that define the apertures 2, are coated with a parylene coating 13. It is inherent to the previously mentioned manufacturing process that this top side at the transition to the upstanding walls 14 is rounded and provides for a smooth skin sensation. The bottom, blade side 9 has cut-aways 10, surrounded by flat annular parts 12 of the metal sheet 3. The upstanding walls 14 of the apertures 2 extend from the blade side to the hair-receiving side. The cutter 11 is moved underneath the blade side, this movement is indicated by a double-sided arrow. The thickness of the foil 1 is indicated by “t”.

### EXAMPLE

A shaving foil was prepared using electroforming. The foil had a thickness of 40 μm, having circular apertures with a radius of 300-400 μm. Subsequently a parylene C coating was applied in a vacuum chamber, using a temperature of 80° C. The parylene coating had a thickness of 5-10 μm, as measured by a micrometer screw gauge. The shaving foil was subjected to tests according to NEN1811 and NEN12472. In both cases the nickel release was <0.2 μg/cm²/week.

1. A two-sided metal foil for use in an electrical shaver, which has a hair-receiving side and an opposite blade side, comprising a sheet of metal with a plurality of apertures through the sheet, in which at least the hair-receiving side of the foil is provided with a coating of poly(p-xylylene) and/or its derivatives, wherein the thickness of the coating is in the range of 1-10 micrometres.

2. The metal foil according to claim 1, wherein the coating of poly(p-xylylene) and/or its derivatives is conformal.

3. The metal foil according to claim 1, wherein the coating is a halogen containing poly(p-xylylene).

4. The metal foil according to claim 1, wherein the coating is poly(chloro-p-xylylene).

5. The metal foil according to claim 1, wherein all faces of the foil are provided with a coating of poly(p-xylylene) and/or its derivatives.

6. The metal foil according to claim 1, wherein the thickness of the coating is in the range of 3-5 micrometres.

7. The metal foil according to claim 1, wherein the metal of the metal sheet is nickel.

8. The metal foil according to claim 1, wherein the functional apertures are in the range of 200-600 micrometres in diameter.

9. The metal foil according to claim 1, wherein the foil has a thickness in the range of 30-60 micrometres.

10. The metal foil according to claim 1, wherein at the blade side the plate partition comprises cut-aways, and surrounding cut-aways the plate partition comprises a flat surface parallel to the foil plane.

11. A method of manufacturing a metal foil according to claim 1, comprising:
exposing a two-sided metal foil, which has a hair-receiving side and an opposite blade side, comprising a sheet of metal with a plurality of apertures through the sheet, to a gas of paracyclophane and/or one or more of its derivatives, thereby depositing a coating of poly(p-xylylene) and/or its derivatives with a thickness in the range of 1-10 micrometres onto the foil.

12. An electrical shaver comprising a metal foil according to claim 1.
